(19) United States
(12) Patent Application Publication
(10) Pub. No.: US 2014/0218845 A1
(43) Pub. Date: Aug. 7, 2014

(54) CHASSIS OF ELECTRONIC DEVICE

(71) Applicants: HONG FU JIN PRECISION INDUSTRY (ShenZhen) CO., LTD., (US); HON HAI PRECISION INDUSTRY CO., LTD., New Taipei (TW)

(72) Inventors: WEN-TANG PENG, New Taipei (TW); HAI-CHEN ZHOU, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/859,712

(22) Filed: Apr. 9, 2013

(30) Foreign Application Priority Data
Feb. 5, 2013 (CN) 201310043239.2

(51) Int. Cl. H05K 5/02

(52) U.S. Cl. CPC H05K 5/0217
USPC 361/679.01

(57) ABSTRACT

A chassis of an electronic device includes a bottom plate, a partition plate extending up from the bottom plate, a tray slidable relative to the bottom plate, a slide base slidably connected to the bottom plate, a foldable first linkage pole group rotatably connected to an end of the slide base for receiving a cable, and a foldable second linkage pole group rotatably connected to an opposite end of the slide base for receiving the cable. An end of the first linkage pole group away from the slide base is rotatably connected to the tray. An end of the second linkage pole group away from the slide base is rotatably connected to the partition plate.

### BACKGROUND

1. Technical Field

The present disclosure relates to a chassis of an electronic device.

2. Description of Related Art

A plurality of trays may be mounted in a chassis of a server. Hard disk drives (HDDs) and connectors are mounted in each tray. The HDDs are electrically connected to the connectors, and the connectors are electrically connected to a backplane by cables. However, the cables are generally untidy. When the trays are pulled, the cables are easily tangled.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a chassis, wherein the chassis includes a linkage mechanism including a slide base and a first linkage pole.

FIG. 2 is an enlarged view of a circled portion II of FIG. 1.

FIG. 3 is an exploded, isometric view of the linkage mechanism of FIG. 1.

FIG. 4 is an enlarged view of the slide base of FIG. 3.

FIG. 5 is an enlarged view of the first linkage pole of FIG. 3, but viewed from a different perspective.

FIG. 6 is an assembled, isometric view of FIG. 1.

FIG. 7 is similar to FIG. 6, but showing a different state.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

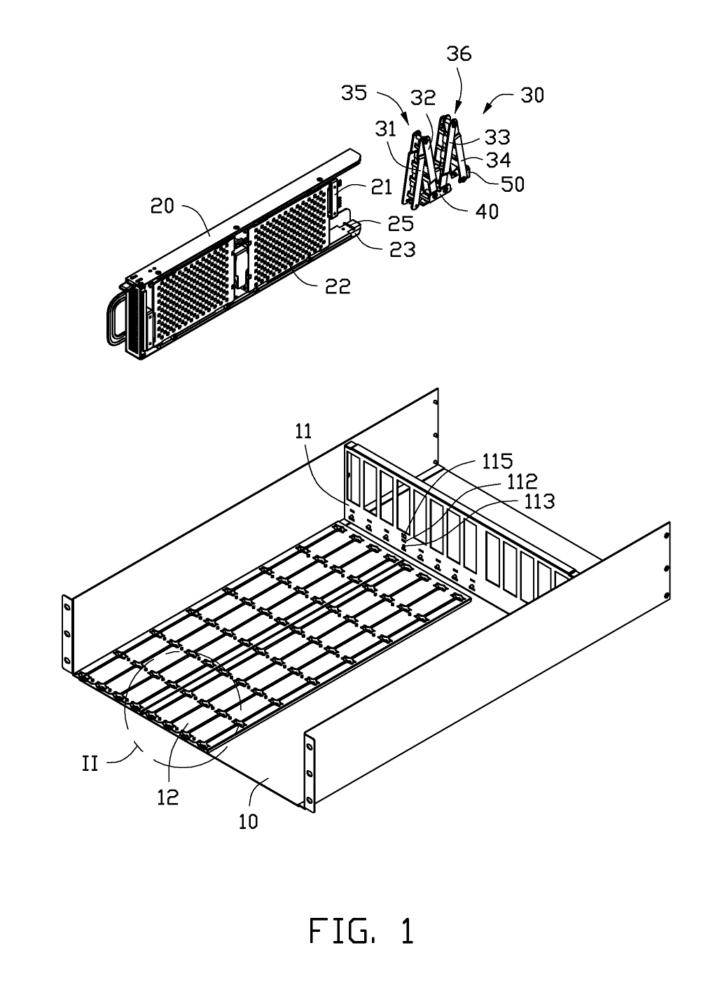

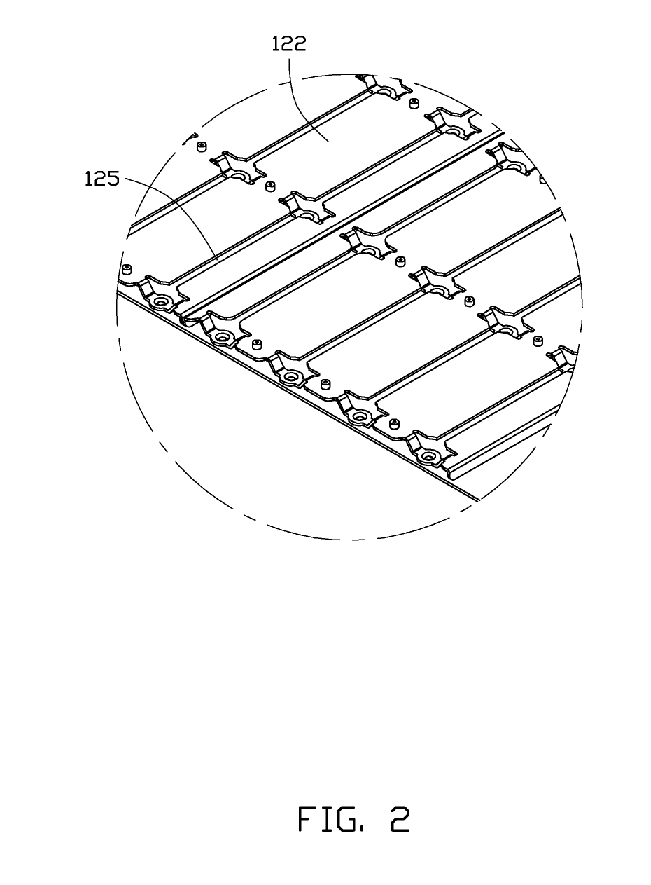

FIGS. 1 and 2 show an exemplary embodiment of a chassis of an electronic device. The chassis includes a bottom plate 10, a tray 20, and a linkage mechanism 30. The linkage mechanism 30 includes a first linkage pole group 35, a second linkage pole group 36, a slide base 40, and a fastening base 50. In the embodiment, the first linkage pole group 35 includes a first linkage pole 31 and a second linkage pole 32. The second linkage pole group 36 includes a third linkage pole 33 and a fourth linkage pole 34.

A partition plate 11 perpendicularly extends up from the bottom plate 10. A slide rail 12 is mounted on the bottom plate 10, located in front of the partition plate 11. The partition plate 11 defines two mounting holes 112 arranged up and down, a through hole 113 located between the mounting holes 112, and a through hole 115 located above the mounting holes 112. The slide rail 12 includes a slide wall 122 spaced from and parallel to the bottom plate 10. A slide slot 125 is defined in the slide wall 122, extending through opposite ends of the slide wall 122 and perpendicular to the partition plate 11.

A connector 21 and an electronic component 22 electrically connected to the connector 21 are mounted in the tray 20. In the embodiment, the electronic component 22 is a hard disk drive (HDD). A mounting plate 23 is formed on a rear end of the tray 20. A pivoting pole 25 protrudes from a top surface of the mounting plate 23, extending beyond opposite sides of the mounting plate 23.

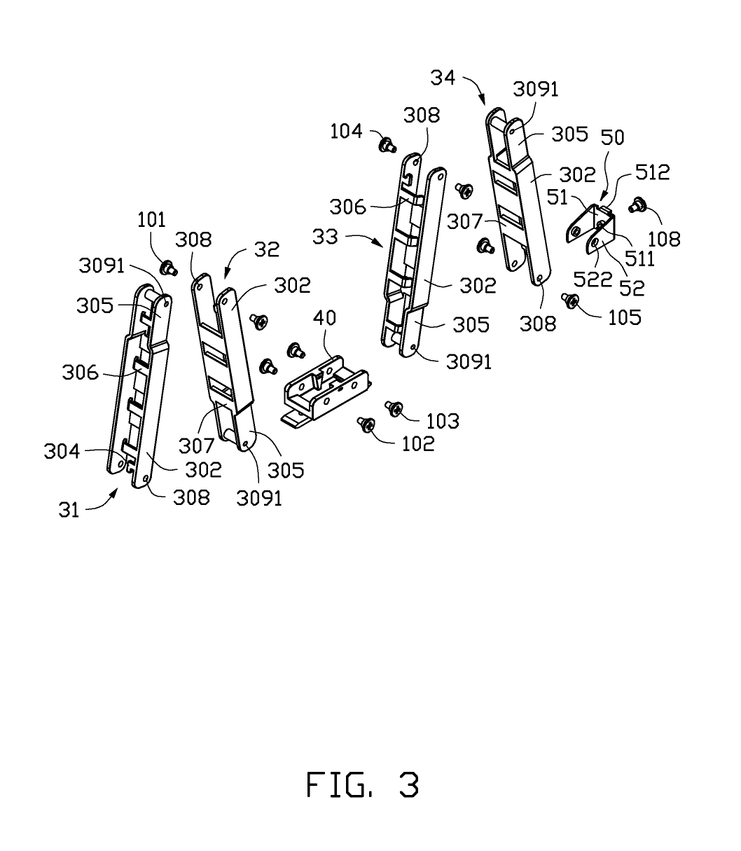

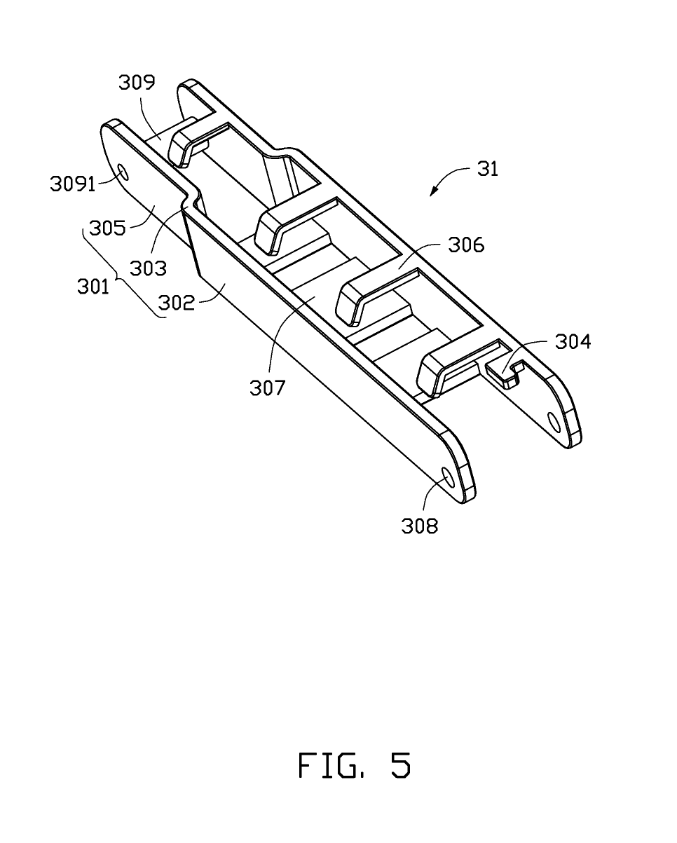

FIGS. 3 and 5 show the first linkage pole 31, the second linkage pole 32, the third linkage pole 33, and the fourth linkage pole 34 with the same structure, each including two opposite pole bodies 301. Each pole body 301 includes a first pole portion 302, a bent portion 303 slantingly extending from an end of the first pole portion 302 toward the opposite pole body 301, and a second pole portion 305 extending from a distal end of the bent portion 303 opposite to the first pole portion 302. A plurality of stop tabs 307 is connected between first sides of the opposite pole bodies 301. A plurality of clips 306 extends from a second side of one of the pole bodies 301 toward the other pole body 301. A through hole 308 is defined in each first pole portion 302, away from the second pole portions 305. A connection pole 309 is connected between the second pole portions 305, away from the first pole portions 302. A locking hole 3091 is axially defined in the connection pole 309, extending through the second pole portions 305. An L-shaped hook 304 extends from the second side of the one of the pole bodies 301, located between the outmost clip 306 away from the connection pole 309 and the through hole 308 and extending toward the other pole body 301.

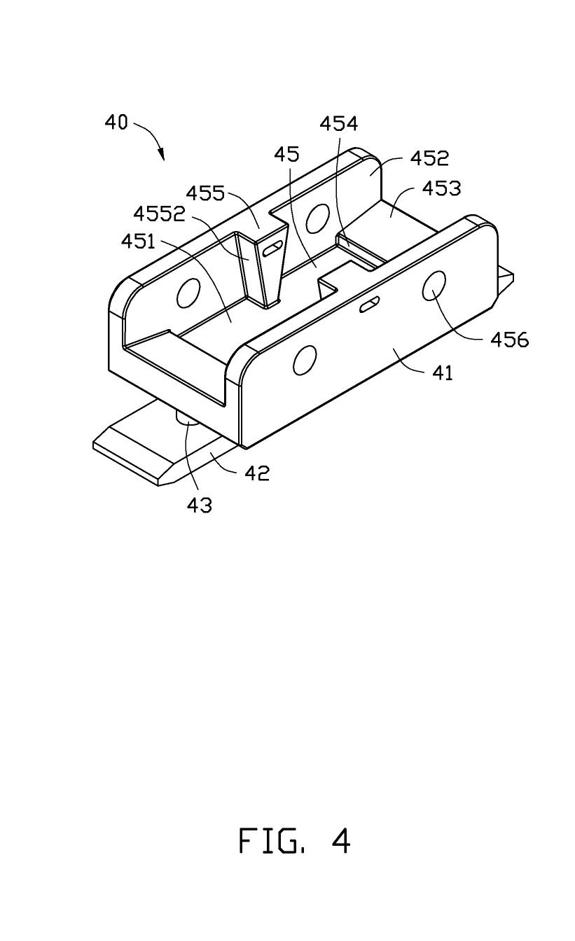

FIG. 4 shows that the slide base 40 includes a main body 41, a slide plate 42 below the main body 41, and a neck 43 connected between the main body 41 and the slide plate 42. A groove 45 is defined in a top of the main body 41, extending through opposite ends of the main body 41. The groove 45 includes a bottom wall 451 and two opposite sidewalls 452. Two platforms 454 protrude from opposite ends of the bottom wall 451. A slanting surface 453 is formed on a top of each platform 454, gradually descending toward a middle of the main body 41. A block 455 extends from a middle of an inner surface of each sidewall 452. Two slanting surfaces 4552 are formed on opposite sides of each block 455, respectively facing the platforms 454. Two through holes 456 are defined in each sidewall 452, located at opposite sides of the corresponding block 455.

FIG. 3 shows that the fastening base 50 includes a base plate 51 and two side plates 52 extending from opposite sides of the base plate 51. The base plate 51 defines a locking hole 511. Two mounting tabs 512 extend from top and bottom sides of the base plate 51, away from the side plates 52. Each side plate 52 defines a locking hole 522.

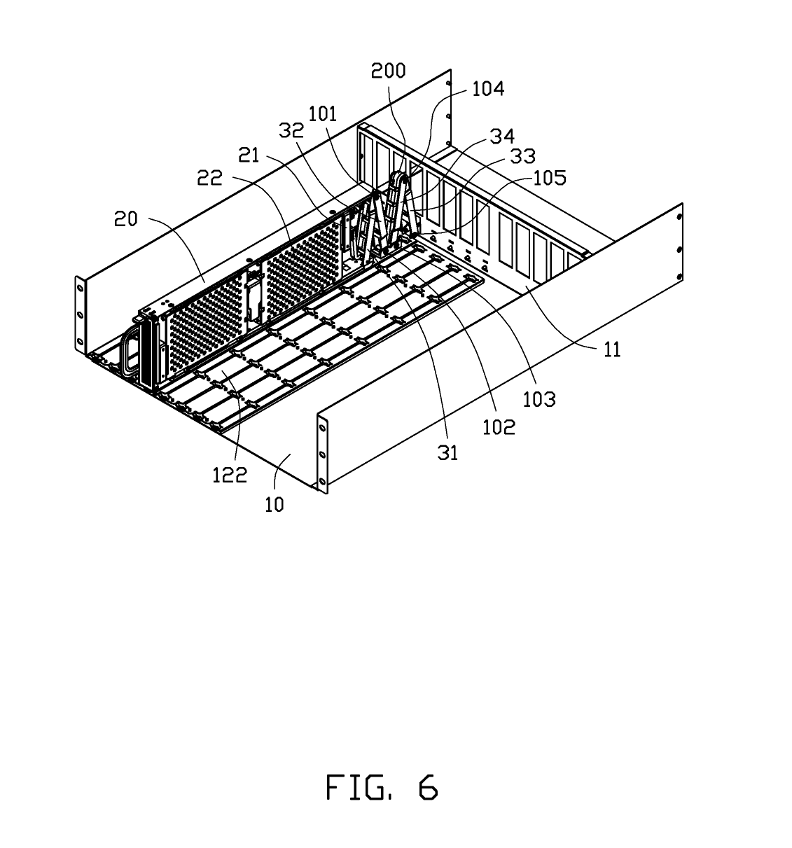

FIGS. 1 and 6 show that in assembly, the second pole portions 305 of the first linkage pole 31 are placed between the first pole portions 302 of the second linkage pole 32. Two screws 101 extend through the through holes 308 of the second linkage pole 32, and engage in the locking hole 3091 of the first linkage pole 31, to rotatably connect the first linkage pole 31 to the second linkage pole 32. The second pole portions 305 of the second linkage pole 32 are received in the groove 45. Two screws 102 extend through two opposite through holes 456 and engage in the locking hole 3091 of the second linkage pole 32, to rotatably connect the second linkage pole 32 to the slide base 40. The second pole portions 305 of the third linkage pole 33 are received in the groove 45. Two screws 103 extend through the other two opposite through holes 456 and engage in the locking hole 3091 of the third linkage pole 33, to rotatably connect the third linkage pole 33 to the slide base 40. The second pole portions 305 of the fourth linkage pole 34 are placed between the first pole portions 302 of the third linkage pole 33. Two screws 104 extend through the through holes 308 of the third linkage pole 33, and engage in the locking hole 3091 of the fourth linkage pole 34, to rotatably connect the fourth linkage pole 34 to the third linkage pole 33. The side plates 52 of the fastening base 50 are placed between the first pole portions 302 of the fourth linkage pole 34. Two screws 105 extend through the through holes 308 of the fourth linkage pole 34, and engage in the locking holes 522, to rotatably connect the fourth linkage pole 34 to the fastening base 50. Opposite ends of the pivoting pole 25 engage in the through holes 308 of the first linkage pole 31, to rotatably connect the first linkage pole 31 to the mounting plate 23. A side of the first linkage pole 31 with the clips 306 faces the tray 20. A side of the second linkage pole 32 with the clips 306 is acute-angled about the slide base 40. A side of the third linkage pole 33 with the clips 306 is acute-angled about the slide base 40. A side of the fourth linkage pole 34 with the clips 306 is acute-angled about the fastening base 50.

The fastening base 50 is placed behind the slide base 40. The fastening base 50 is placed on the slide wall 122. The slide plate 42 enters a space between the slide wall 122 and the bottom plate 10 from a front end of the slide rail 12. The neck 43 slidably enters the slide slot 125. The main body 41 is supported on the slide wall 122. The tray 20 is pushed back, to allow the slide base 40, the fastening base 50, and the tray 20 to move back along the slide wall 122. The first linkage pole 31 is rotated relative to the second linkage pole 32, until the bent portions 303 of the first linkage pole 31 abut against the first pole portions 302 of the second linkage pole 32. Thus, the first linkage pole group 35 is folded. The second linkage pole 32 is rotated relative to the slide base 40, until the second pole portions 305 of the second linkage pole 32 abut against the front slanting surfaces 4552 of the blocks 455. The third linkage pole 33 is rotated relative to the slide base 40, until the second pole portions 305 of the third linkage pole 33 abut against the rear slanting surfaces 4552 of the blocks 455. The fourth linkage pole 34 is rotated relative to the third linkage pole 33, until the bent portions 303 of the fourth linkage pole 34 abut against the first pole portions 302 of the third linkage pole 33. Therefore, the second linkage pole group 36 is folded. The hook 304 of the fourth linkage pole 34 engages with a top side of the corresponding side plate 52. The base plate 51 abuts against the partition plate 11. The mounting tabs 512 engage in the mounting holes 112. A screw 108 extends through the through hole 113 and engages in the locking hole 511, to fasten the fastening base 50 to the partition plate 11.

A first end of a cable 200 is electrically connected to the connector 21. The clips 306 are pulled outward, to allow the cable 200 to extend through the first linkage pole 31, the second linkage pole 32, the third linkage pole 33, and the fourth linkage pole 34. The clips 306 are released to be restored. The cable 200 is positioned between the clips 306 and the stop tabs 307. A second end of the cable 200 extends through the through hole 115, and may be electrically connected to a backplane.

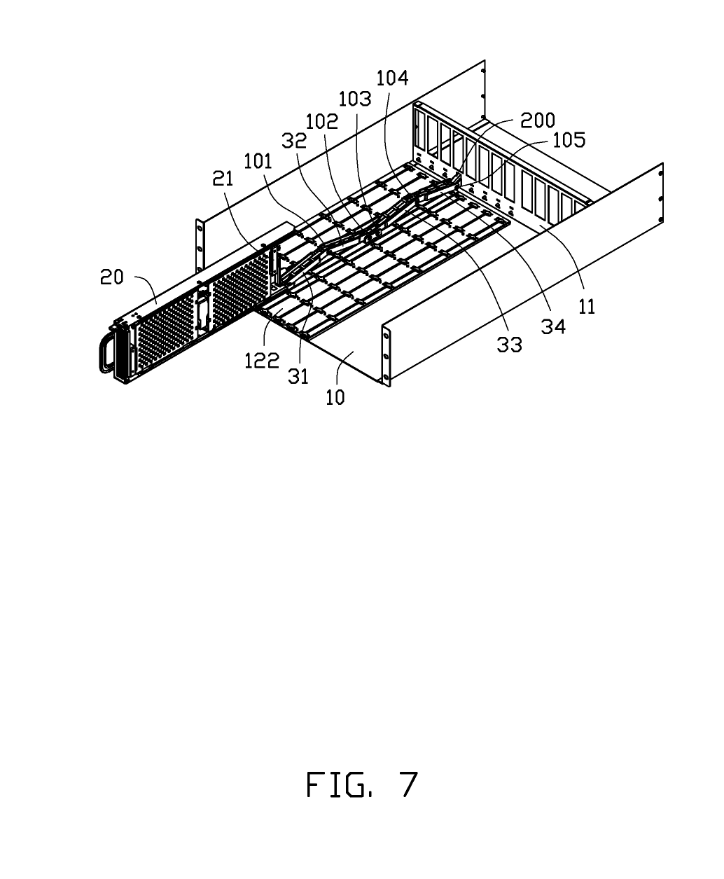

FIG. 7 shows the tray 20 being pulled forward. The first linkage pole 31 is unfolded relative to the second linkage pole 32. The second linkage pole 21 pulls the slide base 40. The slide base 40 slides forward along the slide wall 122, to unfold the third linkage pole 33 relative to the fourth linkage pole 34. When the second linkage pole 32 rotates to abut against the front slanting surface 453, the third linkage pole 33 rotates to abut against the rear slanting surface 453, the tray 20 slides to a largest distance. The purpose of the slide base 40 forming the slanting surfaces 453 is to prevent the first, second, third, and fourth linkage poles 31, 32, 33, and 34 from becoming collinear under the tray 20 and the slide base 40 sliding, to avoid the first, second, third, and fourth linkage poles 31, 32, 33, and 34 being disable to rotate.

The cable 200 is received in the first, second, third, and fourth linkage poles 31, 32, 33, and 34, thus avoiding untidy placement.

In a second embodiment, the fastening base 50 is integrated with the partition plate 11.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A chassis of an electronic device, comprising:
a bottom plate;
a partition plate extending up from the bottom plate;
a tray slidable relative to the bottom plate;
a slide base slidably connected to the bottom plate;
a foldable first linkage pole group rotatably connected to a first end of the slide base and for receiving a cable, an end of the first linkage pole group away from the slide base rotatably connected to the tray; and
a foldable second linkage pole group rotatably connected to a second end of the slide base, opposite to the first end, and for receiving the cable, an end of the second linkage pole group away from the slide base rotatably connected to the partition plate.

2. The chassis of claim 1, wherein the first linkage pole group comprises a first linkage pole and a second linkage pole, the second linkage pole group comprises a third linkage pole and a fourth linkage pole, a first end of the first linkage pole is rotatably connected to the tray, a first end of the second linkage pole is rotatably connected to a second end of the first linkage pole, a second end of the second linkage pole is rotatably connected to the slide base, a first end of the fourth linkage pole is rotatably connected to the partition plate, a second end of the fourth linkage pole is rotatably connected to a first end of the third linkage pole, a second end of the third linkage pole is rotatably connected to the slide base.

3. The chassis of claim 2, wherein two slanting surfaces are formed on opposite ends of the slide base, gradually descending toward a middle of the slide base, when the first and second linkage pole groups are unfolded, the second linkage pole rotates to abut against the slanting surface near the second linkage pole, the third linkage pole rotates to abut against the slanting surface near the third linkage pole.

4. The chassis of claim 3, wherein a groove is defined in the slide base, extending through a top of the slide base, two platforms protrude from opposite ends of a bottom wall bounding the groove, the slanting surfaces are formed on the platforms.

5. The chassis of claim 2, wherein each of the first, second, third, and fourth linkage poles comprises two opposite pole bodies.

6. The chassis of claim 5, wherein each pole body comprises a first pole portion, a bent portion slantingly extending from the first pole portion toward the opposite pole body, and a second pole portion extending from a distal end of the bent portion and away from the first pole portion, the first pole portions of the first linkage pole are rotatably connected to the tray, the second pole portions of the first linkage pole are rotatably connected to the first pole portions of the second linkage pole, the second pole portions of the second linkage pole and the second pole portions of the third linkage pole are rotatably connected to the slide base, the first pole portions of the third linkage pole are rotatably connected to the second pole portions of the fourth linkage pole, the first pole portions of the fourth linkage pole are rotatably connected to the partition plate.

7. The chassis of claim 5, wherein a plurality of stop tabs is connected between first sides of the opposite pole bodies, a plurality of clips extends from a second side of one of the pole bodies toward the opposite pole body, the cable is positioned between the stop tabs and the clips.

8. The chassis of claim 5, wherein a slide rail is mounted on the bottom plate, the slide rail comprises a slide wall spaced from the bottom plate, the slide wall defines a slide slot, the slide base comprises a main body slidably supported on the slide wall, a slide plate slidably received between the slide wall and the bottom plate, and a neck connected between the main body and the slide plate, the neck slidably received in the slide slot.

9. The chassis of claim 8, wherein the main body defines a groove extending through a top of the main body, the groove comprise two opposite sidewalls, the pole bodies of the second linkage pole are rotatably connected to first ends of the sidewalls, the pole bodies of the third linkage pole are rotatably connected to second ends of the sidewalls.

10. The chassis of claim 9, wherein a block extends from a middle of each sidewall, two slanting surfaces are formed on opposite sides of each block, respectively facing the second linkage pole and the third linkage pole, when the first and second linkage pole groups are folded, the pole bodies of the second linkage pole rotate to abut against the slanting surfaces facing the second linkage pole, the pole bodies of the third linkage pole rotate to abut against the slanting surfaces facing the third linkage pole.

11. The chassis of claim 5, wherein a fastening base is mounted to the partition plate, the fastening base comprises two parallel side plates, the pole bodies of the fourth linkage pole are rotatably connected to the side plates.

12. The chassis of claim 11, wherein a hook extends from one of the pole bodies of the fourth linkage pole and engages with the corresponding side plate.

13. The chassis of claim 1, wherein a connector is mounted in the tray, the cable is electrically connected to the connector and extends through the partition plate.

14. A chassis of an electronic device, comprising:
a bottom plate;
a partition plate extending up from the bottom plate;
a tray slidable relative to the bottom plate; and
a foldable linkage pole group for receiving a cable, a first end of the linkage pole group rotatably connected to the tray, a second end of the linkage pole group rotatably connected to the partition plate.
